(19) United States
(12) Patent Application Publication
(10) Pub. No.: US 2025/0357360 A1
(43) Pub. Date: Nov. 20, 2025

(54) SUBSTRATE INCLUDING ALIGNMENT MARK AND EDGE DETECTION DEVICE FOR SUBSTRATE INCLUDING ALIGNMENT MARK

(71) Applicant: Sharp Display Technology Corporation, Kameyama City (JP)

(72) Inventor: Tadashi KITABAYASHI, Kameyama City, (JP)

(21) Appl. No.: 19/195,349

(22) Filed: Apr. 30, 2025

(30) Foreign Application Priority Data
May 15, 2024 (JP) 2024-079608

(51) Int. Cl. H01L 23/544; G02F 1/1345; G02F 1/1362; H01L 21/68

(52) U.S. Cl. CPC H01L 23/544; G02F 1/13452; G02F 1/136286; H01L 21/681; H01L 2223/54426

(57) ABSTRACT

An active matrix substrate that is a substrate including an alignment mark includes an active matrix substrate and an alignment mark provided on part of a first surface that is a surface on one side of the active matrix substrate, and each of the active matrix substrate and the alignment mark has a cutting line, and the cutting line of the alignment mark coincides with the cutting line of the active matrix substrate in a plan view.

### CROSS-REFERENCE TO RELATED APPLICATIONS

This application claims the benefit of priority to Japanese Patent Application Number 2024-079608 filed on May 15, 2024. The entire contents of the above-identified application are hereby incorporated by reference.

### BACKGROUND

### Technical Field

The disclosure relates to a substrate including an alignment mark and an edge detection device for a substrate including an alignment mark.

In various fields, research and development for more effectively utilizing an alignment mark provided on a substrate have been actively conducted. For example, JP 2002-9315 A describes a method for improving a recognition rate of the alignment mark, and JP 2006-29892 A describes an edge position detection device that accurately measures a line width of a mark and detects an edge position of the mark on a substrate.

### SUMMARY

According to the method for improving the recognition rate of the alignment mark described in JP 2002-9315 A, the problem that may occur when the alignment mark provided on the substrate is not recognized is solved. Further, according to the edge position detection device described in JP 2006-29892 A, the edge position of the mark can be detected by accurately measuring the line width of the mark. However, for example, in a step of singulation by partitioning a mother substrate into a plurality of substrates, variations may occur in the positions of the alignment marks in the plurality of singulated substrates due to a partition tolerance that may occur. When the positions of the alignment marks vary as described above, a variation also occurs in a position of an edge of the substrate detected based on the position of the alignment mark in each of the plurality of singulated substrates. Thus, there is a problem in that the position of the edge of the substrate cannot be accurately detected. In addition, as a known edge detection method, there is known a method of detecting an edge by setting a threshold value between a luminance difference between a detection target portion and a surrounding portion or setting a threshold value for a luminance change rate (differential processing). However, in the case of such a known edge detection method, there is a problem in that luminance/contrast of an obtained image changes due to a variation in luminance of a light source, a variation in an angle of a detection target object with respect to the light source, a blur of an image, and the like, and thus a deviation occurs in a relationship with the threshold value, an error occurs, stable detection becomes difficult, and a processing time becomes long.

An object of one aspect of the disclosure is to provide a substrate including an alignment mark that can accurately detect a position of an edge of the substrate, and an edge detection device for a substrate including an alignment mark that can accurately detect a position of the edge of the substrate stably and in a relatively short time.

In order to achieve the above object, the substrate including an alignment mark of the disclosure includes a substrate and an alignment mark provided on part of a first surface that is a surface on one side of the substrate, in which each of the substrate and the alignment mark has a cutting line, and
the cutting line of the alignment mark coincides with the cutting line of the substrate in a plan view.

In order to achieve the above object, the edge detection device for a substrate including an alignment mark of the disclosure includes
a mounting stand on which the substrate including an alignment mark is mounted,
a function unit including an image taking portion configured to image the alignment mark,
a memory unit in which data of a first image in a plan view of the alignment mark including an edge of the alignment mark at which a cutting line of the alignment mark is located, obtained from the image taking portion, is stored, and
a control unit configured to detect a position of part of the edge of the substrate by comparing data of a second image in a plan view of the alignment mark including the edge of the alignment mark at which the cutting line of the alignment mark is located, obtained from the image taking portion, with the data of the first image in the memory unit, in which one of the mounting stand and the function unit is movable with respect to the other of the mounting stand and the function unit in each of an X direction, a Y direction, and a Z direction.

According to an aspect of the disclosure, it is possible to provide the substrate including an alignment mark that can accurately detect the position of the edge of the substrate and the edge detection device for a substrate including an alignment mark.

### BRIEF DESCRIPTION OF DRAWINGS

The disclosure will be described with reference to the accompanying drawings, wherein like numbers reference like elements.

FIG. 1 is a plan view of a display device according to a first embodiment when viewed from a second surface side of an active matrix substrate.

FIG. 2 is an enlarged view of an alignment mark provided on a first surface of the active matrix substrate of the display device according to the first embodiment when viewed from the second surface side of the active matrix substrate.

FIG. 3 is a view of the alignment mark provided on the first surface of the active matrix substrate of the display device according to the first embodiment when viewed from a side surface side of the active matrix substrate.

FIG. 4 is a perspective view illustrating part of the display device according to the first embodiment.

FIG. 5 is a cross-sectional view taken along a line A-A′ of the display device according to the first embodiment illustrated in FIG. 1.

FIG. 6 is a view illustrating a schematic configuration of an edge detection device for the active matrix substrate including an alignment mark provided in the display device according to the first embodiment.

FIG. 7 is a diagram for describing steps of applying conductive resins to predetermined positions of the display device according to the first embodiment using the edge detection device illustrated in FIG. 6.

FIG. 8 is a view for describing a step of detecting a position of part of an edge of the active matrix substrate by comparing data of a first image with data of a second image performed in the edge detection device illustrated in FIG. 6.

FIG. 9 is a view illustrating a case where a nozzle for discharging a conductive resin is moved to an application position of the conductive resin detected by the edge detection device illustrated in FIG. 6 when the display device according to the first embodiment is partitioned from a mother display device including a plurality of display devices without a partition tolerance.

FIG. 10 is a view illustrating a case where the nozzle for discharging the conductive resin is moved to the application position of the conductive resin detected by the edge detection device illustrated in FIG. 6 when the display device according to the first embodiment is partitioned from the mother display device including the plurality of display devices with a positive partition tolerance.

FIG. 11 is a view illustrating a case where the nozzle for discharging the conductive resin is moved to the application position of the conductive resin detected by the edge detection device illustrated in FIG. 6 when the display device according to the first embodiment is partitioned from the mother display device including the plurality of display devices with a negative partition tolerance.

FIG. 12 is a view for describing a step in which the edge detection device illustrated in FIG. 6 detects a position of part of an edge of an active matrix substrate including a known alignment mark.

FIG. 13 is a view illustrating a case where the nozzle for discharging the conductive resin is moved to the application position of the conductive resin detected by the edge detection device illustrated in FIG. 6 when a known display device is partitioned from the mother display device including the plurality of display devices without a partition tolerance.

FIG. 14 is a view illustrating a case where the nozzle for discharging the conductive resin is moved to the application position of the conductive resin detected by the edge detection device illustrated in FIG. 6 when the known display device is partitioned from the mother display device including the plurality of display devices with a positive partition tolerance.

FIG. 15 is a view illustrating a case where the nozzle for discharging the conductive resin is moved to the application position of the conductive resin detected by the edge detection device illustrated in FIG. 6 when the known display device is partitioned from the mother display device including the plurality of display devices with a negative partition tolerance.

FIG. 16 is a view illustrating a case where a function unit of the edge detection device illustrated in FIG. 6 further includes a temperature adjustment portion for adjusting the temperature of a storage unit of the conductive resin.

FIG. 17 is a view illustrating a schematic configuration of an edge detection device including a tilt mechanism that tilts the display device according to the first embodiment including the active matrix substrate including an alignment mark at 45 degrees or less with respect to a plane.

FIG. 18 is a view illustrating a case where the function unit of the edge detection device including the tilt mechanism illustrated in FIG. 17 further includes a light radiation unit.

FIG. 19 is views for describing a step of moving the nozzle for discharging the conductive resin to an application position of the conductive resin detected by the edge detection device illustrated in FIG. 17 and an application step of the conductive resin.

FIG. 20 is views for describing a problem in a step of applying the conductive resin to part of the edge of the active matrix substrate including the known alignment mark.

FIG. 21 is a view for describing finished dimensions of the conductive resin applied to the display device according to the first embodiment.

FIG. 22 is diagrams for describing the degrees of variations in the finished dimensions of the conductive resin applied to the display device according to the first embodiment.

FIG. 23 is diagrams for describing the degrees of variations in finished dimensions of the conductive resin applied to the known display device including the active matrix substrate including the known alignment mark.

### DESCRIPTION OF EMBODIMENTS

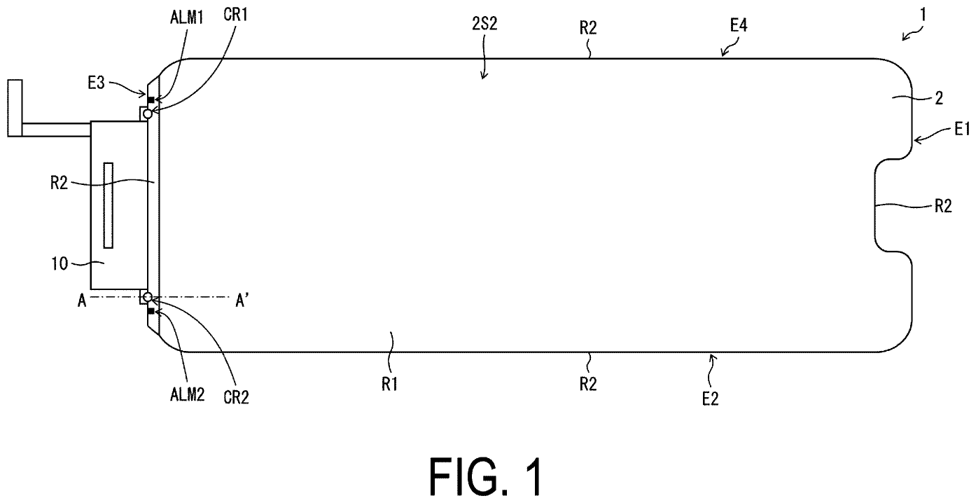

Embodiments of the disclosure will be described with reference to FIG. 1 to FIG. 23 as follows. Hereinafter, for convenience of description, configurations having the same functions as those described in a specific embodiment are denoted by the same reference signs, and descriptions thereof will be omitted.

### First Embodiment

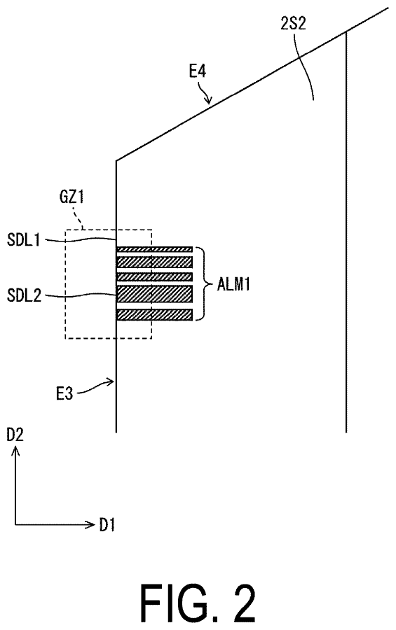

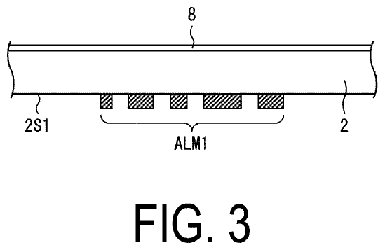

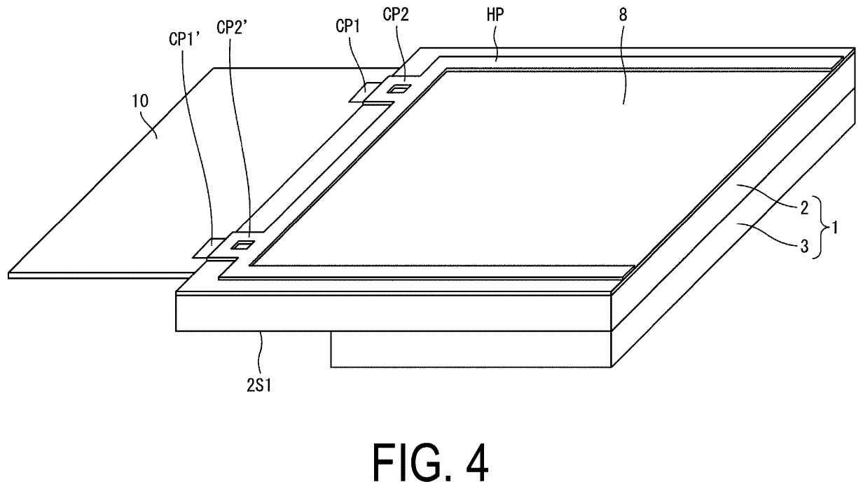

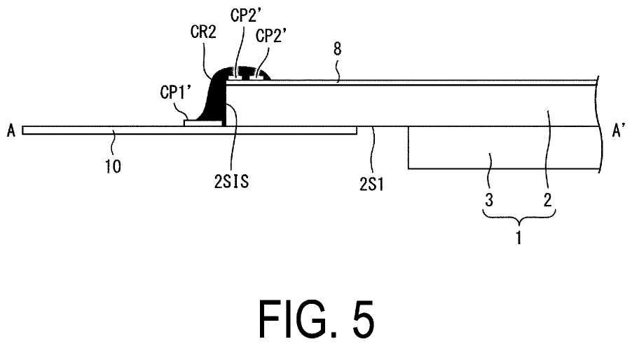

FIG. 1 is a plan view of a display device 1 according to a first embodiment when viewed from a second surface 2S2 side of an active matrix substrate 2. FIG. 2 is an enlarged view of an alignment mark ALM1 provided on a first surface 2S1 of the active matrix substrate 2 of the display device 1 according to the first embodiment when viewed from the second surface 2S2 side of the active matrix substrate 2. FIG. 3 is a view of the alignment mark ALM1 provided on the first surface 2S1 of the active matrix substrate 2 of the display device 1 according to the first embodiment when viewed from a side surface 2SIS side of the active matrix substrate 2. FIG. 4 is a perspective view illustrating part of the display device 1 according to the first embodiment. FIG. 5 is a cross-sectional view taken along a line A-A′ of the display device 1 according to the first embodiment illustrated in FIG. 1.

As illustrated in FIG. 1, the display device 1 includes the active matrix substrate 2 that is a substrate including the alignment marks ALM1 and ALM2. In the present embodiment, as illustrated in FIGS. 4 and 5, a counter substrate 3 is provided on the first surface 2S1 side of the active matrix substrate 2. Although not illustrated, a plurality of pixel electrodes are provided on the first surface 2S1 of the active matrix substrate 2, and the counter substrate 3 is provided so as to face the plurality of pixel electrodes. In the present embodiment, a liquid crystal layer (not illustrated) is further provided between the plurality of pixel electrodes of the active matrix substrate 2 and the counter substrate 3. In a case of a twisted nematic (TN) type in which liquid crystal molecules included in the liquid crystal layer are controlled by a vertical electrical field, a common counter electrode facing the plurality of pixel electrodes is provided on the counter substrate 3. In a case of an in plane switching (IPS) type in which liquid crystal molecules included in the liquid crystal layer are controlled by a transverse electrical field, a common counter electrode together with the plurality of pixel electrodes are provided on the first surface 2S1 of the active matrix substrate 2. As described above, in the present embodiment, an example will be described in which the display device 1 is a liquid crystal display device. However, the disclosure is not limited thereto as long as the active matrix substrate 2 that is a substrate including the alignment marks ALM1 and ALM2 is included. For example, the display device may be a display device in which an organic light emitting diode (OLED) or a quantum dot light emitting diode (QLED) is provided as a light-emitting element at a position corresponding to each of the plurality of pixel electrodes of the active matrix substrate 2. In the present embodiment, an example will be described in which the substrate including the alignment marks ALM1 and ALM2 is the active matrix substrate 2. However, the substrate including the alignment marks ALM1 and ALM2 is not limited to the substrate for the display device, and may be a substrate used in various fields other than the display device. The substrate including the alignment marks ALM1 and ALM2 may be, for example, a semiconductor wafer, a flexible printed circuit board, a color filter substrate, a mask, or an IC chip.

The alignment mark ALM1 provided on the first surface 2S1 that is a surface on one side of the active matrix substrate 2 illustrated in FIG. 3 has a cutting line SDL2 as illustrated in FIG. 2. As illustrated in FIG. 1, the active matrix substrate 2 has cutting lines forming an edge E1, an edge E2, an edge E3, and an edge E4. As illustrated in FIG. 2, the cutting line SDL2 of the alignment mark ALM1 coincides with a cutting line SDL1 forming the edge E3 of the active matrix substrate 2 in a plan view. In the present embodiment, as illustrated in FIG. 1, the alignment mark ALM2 is provided together with the alignment mark ALM1 on the first surface 2S1 opposite to the second surface 22 of the active matrix substrate 2. Similarly to the alignment mark ALM1, the alignment mark ALM2 also has a cutting line, and the cutting line of the alignment mark ALM2 coincides with the cutting line SDL1 forming the edge E3 of the active matrix substrate 2 in a plan view. The alignment marks ALM1 and ALM2 can be made of, for example, an Al-based material, a W-based material, and a carbon-based material. As the Al-based material, for example, a layered body of Al—Si, a layered body of Mo—Al—Mo, and a layered body of Ti—Al—TiN can be suitably used, and as the W-based material, a layered body of WTa can be suitably used.

The display device 1 illustrated in FIG. 1 is obtained through a step of singulation by partitioning a mother display device including a plurality of display devices into the plurality of display devices. In this step of singulation, the cutting lines forming the edge E1, the edge E2, the edge E3, and the edge E4 of the active matrix substrate 2 are formed, and when the cutting line forming the edge E3 of the active matrix substrate 2 is formed, the cutting lines of the alignment marks ALM1 and ALM2 are also formed. Thus, the cutting lines of the alignment marks ALM1 and ALM2 coincide with the cutting line forming the edge E3 of the active matrix substrate 2 in a plan view.

As illustrated in FIG. 1, the active matrix substrate 2 provided in the display device 1 includes a first region R1 and second regions R2 each surrounding the first region R1 and including a respective one of the edge E1, the edge E2, the edge E3, and the edge E4 that are all edges of the active matrix substrate 2. In FIG. 1, the second region R2 including the edge E1, the second region R2 including the edge E2, and the second region R2 including the edge E4 are illustrated as having no widths, but actually have predetermined widths like the second region R2 including the edge E3.

As illustrated in FIGS. 1 and 2, each of the alignment marks ALM1 and ALM2 is provided in the second region R2 including the edge E3, in the present embodiment, and is a continuous film formed from the edge E3 of the active matrix substrate 2 in a first direction D1 that is a direction orthogonal to the edge E3. Note that the continuous film means a film not partitioned by a material other than a material constituting the continuous film in one plane. In the present embodiment, as illustrated in FIG. 2, an example will be described in which each of the alignment marks ALM1 and ALM2 is composed of a plurality of, for example, five continuous films formed from the edge E3 of the active matrix substrate 2 in the first direction D1 that is the direction orthogonal to the edge E3 formed along a second direction D2. However, the disclosure is not limited thereto, and each of the alignment marks ALM1 and ALM2 may be composed of one continuous film formed from the edge E3 of the active matrix substrate 2 in the first direction D1 that is the direction orthogonal to the edge E3.

In the active matrix substrate 2 illustrated in FIG. 1, the first region R1 is a display region, the second region R2 is a non-display region, a plurality of pixel electrodes (not illustrated) are provided on the first surface 2S1 in the display region of the active matrix substrate 2, and the alignment marks ALM1 and ALM2 are provided on the first surface 2S1 in the non-display region of the active matrix substrate 2. The alignment marks ALM1 and ALM2 preferably have shapes in which positions of the alignment marks ALM1 and ALM2 in the second direction D2 illustrated in FIG. 2 in captured images obtained from an image taking portion 24 (for example, a camera) described later do not change even when the image taking portion 24 is moved along the first direction D1 that is the partition tolerance direction of the display device 1 illustrated in FIG. 2. As illustrated in FIG. 2, in order to improve the recognition rate, the alignment marks ALM1 and ALM2 are preferably formed such that each of the plurality of continuous films has a predetermined line width and a predetermined line spacing.

As will be described later, in the present embodiment, since the detection of the alignment marks ALM1 and ALM2 provided on the first surface 2S1 of the active matrix substrate 2 is performed from the second surface 2S2 side of the active matrix substrate 2, the active matrix substrate 2 is preferably a glass substrate or an optical transparent resin substrate on which the pixel electrodes and the alignment marks ALM1 and ALM2 are provided.

As illustrated in FIGS. 4 and 5, in the present embodiment, the active matrix substrate 2 includes a flexible printed circuit board 10 including first connection pads CP1 and CP1′. In addition, a wiring line pattern HP including second connection pads CP2 and CP2′ is provided on the second surface 2S2 that is the second region R2 including the edge E3 of the active matrix substrate 2 and is facing the first surface 2S1 in the non-display region. In the present embodiment, a transparent electrode layer 8 made of, for example, indium tin oxide (ITO) is provided on the entire second surface 2S2 of the active matrix substrate 2, and the wiring line pattern HP including the second connection pads CP2 and CP2′ electrically connected to the transparent electrode layer 8 is provided in a peripheral portion of the second surface 22 of the active matrix substrate 2 for the purpose of reducing a resistance of the transparent electrode layer 8. As illustrated in FIG. 5, the flexible printed circuit board 10 is provided on part of the first surface 2S1 in the non-display region of the active matrix substrate 2 so that the first connection pads CP1 and CP1′ are located near the second connection pads CP2 and CP2′, respectively.

As illustrated in FIG. 5, in the active matrix substrate 2 including the alignment marks ALM1 and ALM2 provided in the display device 1, a conductive resin CR2 is provided as a continuous film on at least part of the first connection pad CP1′, at least part of the second connection pad CP2′, and the side surface 2SIS of the edge E3 of part of the active matrix substrate 2 on which the second connection pad CP2′ is provided. Although not illustrated, in the active matrix substrate 2 including the alignment marks ALM1 and ALM2 provided in the display device 1, a conductive resin CR1 is provided as a continuous film on at least part of the first connection pad CP1, at least part of the second connection pad CP2, and the side surface 2SIS of the edge E3 of part of the active matrix substrate 2 on which the second connection pad CP2 is provided. Note that in the present embodiment, a resin containing Ag particles, which are conductive particles, are used as the conductive resins CR1 and CR2. However, the disclosure is not limited thereto. As will be described in detail later, according to the alignment marks ALM1 and ALM2 provided on the active matrix substrate 2, an alignment following a partition tolerance which may occur in the step of singulation by partitioning the mother display device including the plurality of display devices into the plurality of display devices can be performed, and the position of the edge of the active matrix substrate 2 can be accurately detected. Thus, the conductive resins CR1 and CR2 can be accurately and stably applied without being affected by the partition tolerance. In the present embodiment, an example will be described in which the edge E3 of part of the active matrix substrate 2 is accurately detected using the alignment marks ALM1 and ALM2, and the conductive resins CR1 and CR2 are accurately applied to predetermined positions of the edge E3. However, the type of the step is not particularly limited as long as the step is performed based on the positions of the edge of the substrate accurately detected using the alignment marks ALM1 and ALM2.

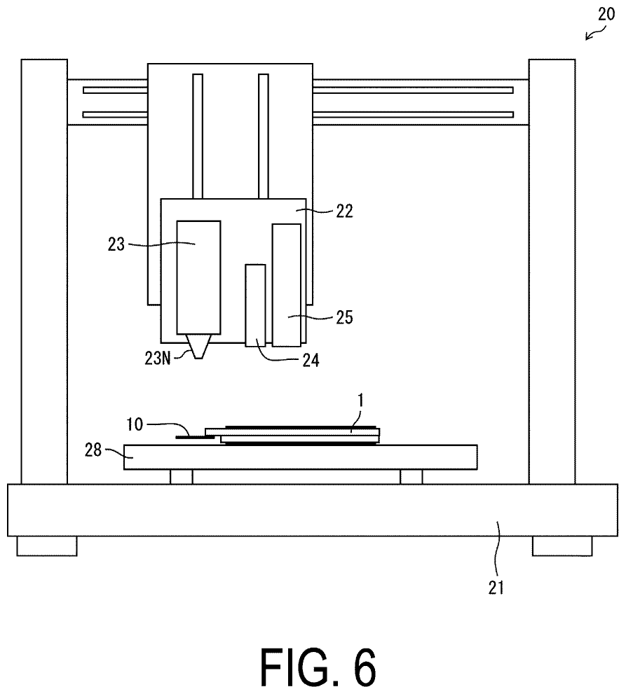

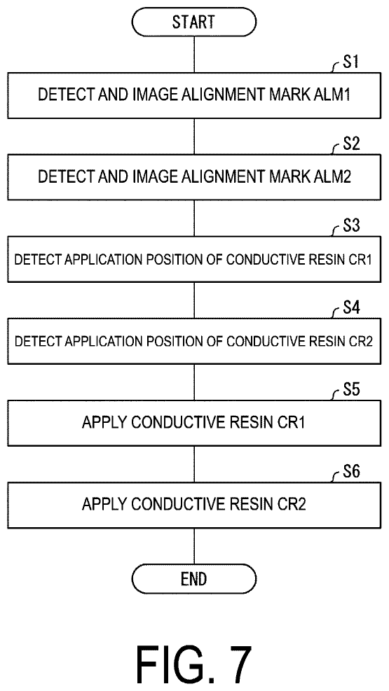

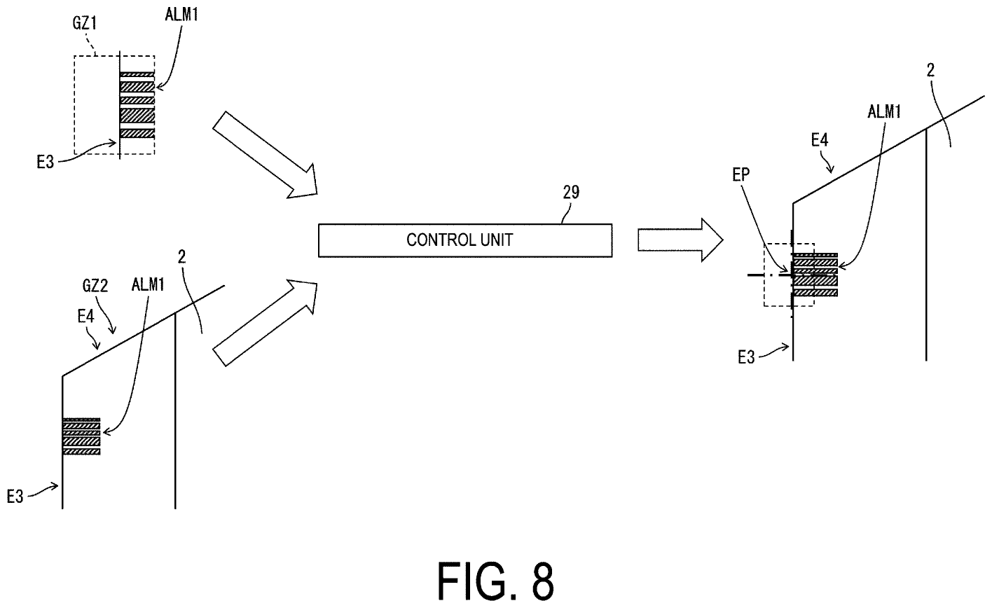

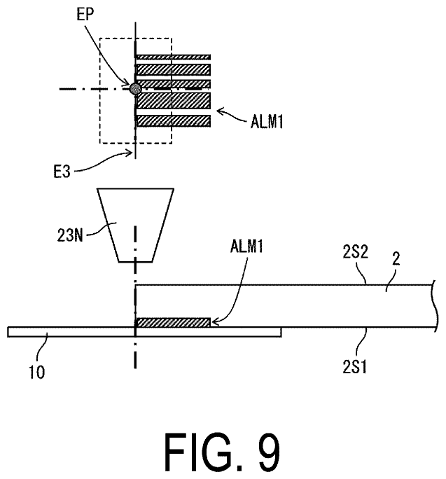

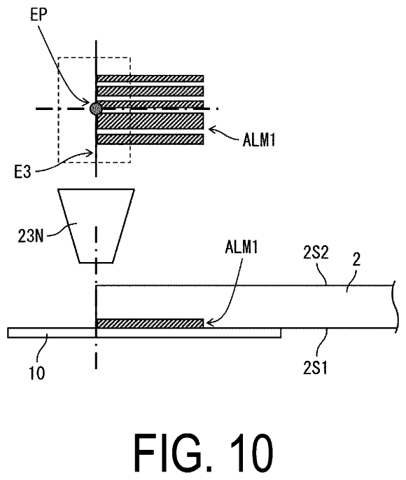

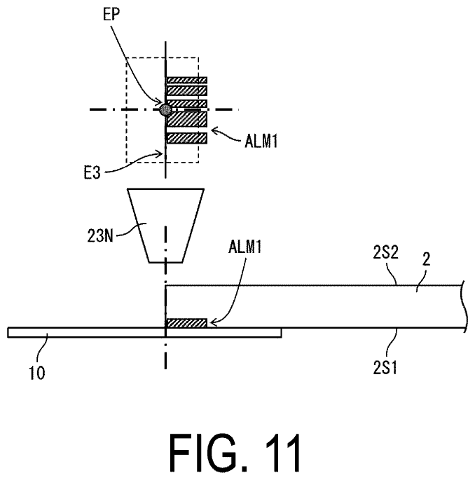

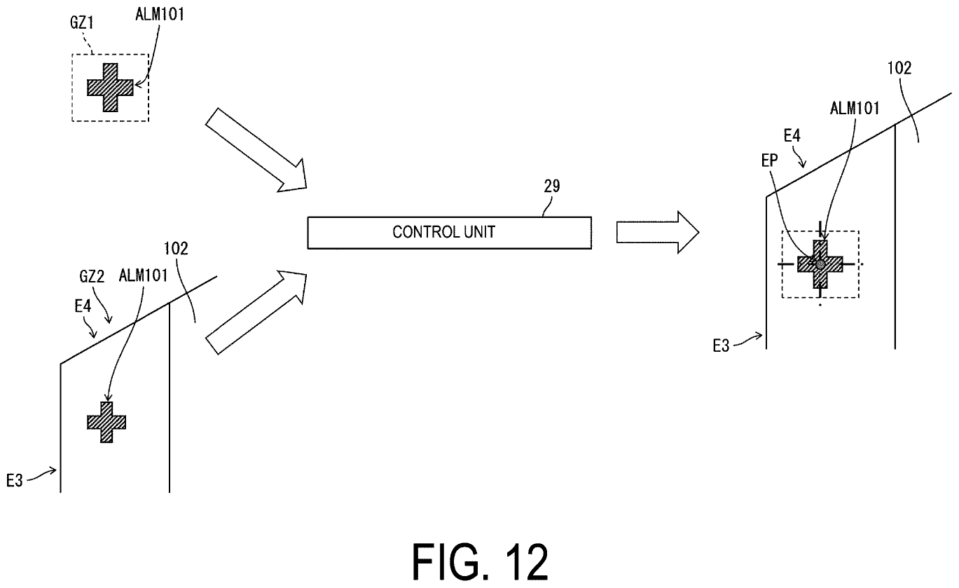

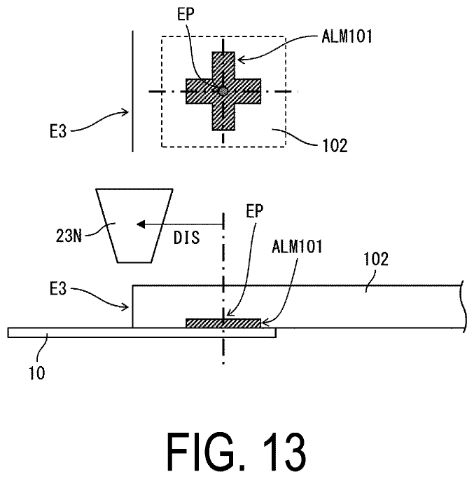

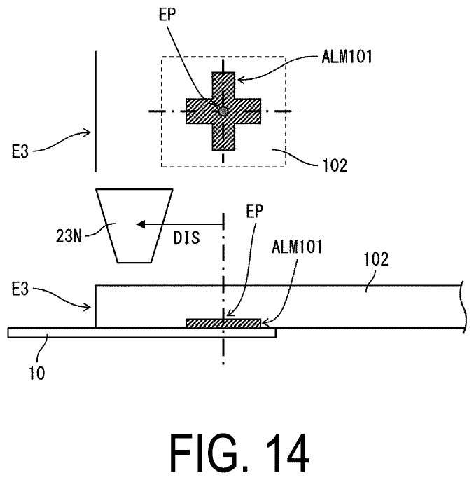

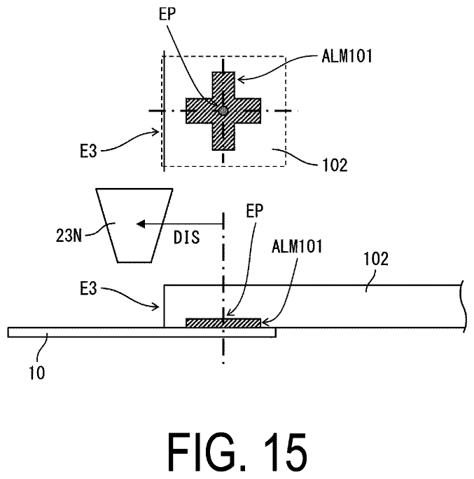

FIG. 6 is a view illustrating a schematic configuration of an edge detection device 20 for the active matrix substrate 2 including the alignment marks ALM1 and ALM2 provided in the display device 1 according to the first embodiment. FIG. 7 is a diagram for describing steps of applying the conductive resins CR1 and CR2 to predetermined positions of the display device 1 according to the first embodiment using the edge detection device 20 illustrated in FIG. 6. FIG. 8 is a view for describing a step of detecting a position of part of the edge E3 of the active matrix substrate 2 by comparing data of a first image GZ1 with data of a second image GZ2 performed in the edge detection device 20 illustrated in FIG. 6. FIG. 9 is a view illustrating a case where a nozzle 23N for discharging the conductive resin CR1 is moved to an application position of the conductive resin CR1 detected by the edge detection device 20 illustrated in FIG. 6 when the display device 1 according to the first embodiment is partitioned from the mother display device including the plurality of display devices without the partition tolerance. FIG. 10 is a view illustrating a case where the nozzle 23N for discharging the conductive resin CR1 is moved to the application position of the conductive resin CR1 detected by the edge detection device 20 illustrated in FIG. 6 when the display device 1 according to the first embodiment is partitioned from the mother display device including the plurality of display devices with a positive partition tolerance. FIG. 11 is a view illustrating a case where the nozzle 23N for discharging the conductive resin CR1 is moved to the application position of the conductive resin CR1 detected by the edge detection device 20 illustrated in FIG. 6 when the display device 1 according to the first embodiment is partitioned from the mother display device including the plurality of display devices with a negative partition tolerance. FIG. 12 is a view for describing a step in which the edge detection device 20 illustrated in FIG. 6 detects a position of part of the edge E3 of an active matrix substrate 102 including a known alignment mark ALM101. FIG. 13 is a view illustrating a case where the nozzle 23N for discharging the conductive resin CR1 is moved to the application position of the conductive resin CR1 detected by the edge detection device 20 illustrated in FIG. 6 when the known display device is partitioned from the mother display device including the plurality of display devices without the partition tolerance. FIG. 14 is a view illustrating a case where the nozzle 23N for discharging the conductive resin CR1 is moved to the application position of the conductive resin CR1 detected by the edge detection device 20 illustrated in FIG. 6 when the known display device is partitioned from the mother display device including the plurality of display devices with a positive partition tolerance. FIG. 15 is a view illustrating a case where the nozzle 23N for discharging the conductive resin CR1 is moved to the application position of the conductive resin CR1 detected by the edge detection device 20 illustrated in FIG. 6 when the known display device is partitioned from the mother display device including the plurality of display devices with a negative partition tolerance.

As illustrated in FIG. 6, the edge detection device 20 includes a mounting stand 28 on which the display device 1 including the active matrix substrate 2 including the alignment marks ALM1 and ALM2 is mounted, a function unit 22 including an image taking portion 24 that images the alignment marks ALM1 and ALM2, a memory unit (not illustrated) in which data of the first image GZ1 in a plan view of the alignment marks ALM1 and ALM2 including the edges of the alignment marks ALM1 and ALM2 at which the cutting line SDL2 (illustrated in FIG. 2) of the alignment marks ALM1 and ALM2, obtained from the image taking portion 24, is located is stored, a control unit (not illustrated) that detects a position of part of the edge E3 of the active matrix substrate 2 by comparing data of the second image GZ2 in a plan view of the alignment marks ALM1 and ALM2 including the edges of the alignment marks ALM1 and ALM2 at which the cutting line SDL2 of the alignment marks ALM1 and ALM2, obtained from the image taking portion 24, is located with the data of the first image GZ1 in the memory unit, and one of the mounting stand 28 and the function unit 22 is movable with respect to the other of the mounting stand 28 and the function unit 22 in each of an X direction that is a right-left direction in FIG. 6, a Y direction that is a depth direction in FIG. 6, and a Z direction that is an up-down direction in FIG. 6. That is, one of the mounting stand 28 and the function unit 22 may be movable with respect to the other of the mounting stand 28 and the function unit 22 in each of the X direction, the Y direction, and the Z direction. In the edge detection device 20, the alignment marks ALM1 and ALM2 provided on the first surface 2S1 of the active matrix substrate 2 are detected from the second surface 2S2 side of the active matrix substrate 2. The memory unit and the control unit may be provided, for example, inside a support unit 21. In the present embodiment, an example will be described in which the function unit 22 moves with respect to the mounting stand 28 in each of the X direction that is a right-left direction in FIG. 6 and the Z direction that is an up-down direction in FIG. 6, and the mounting stand 28 moves with respect to the function unit 22 in the Y direction that is a depth direction in FIG. 6. However, the disclosure is not limited thereto. That is, in the present embodiment, the function unit 22 is movable in the X direction and the Z direction and fixed in the Y direction with respect to the fixed support unit 21, and the mounting stand 28 is movable in the Y direction and fixed in the X direction and the Z direction with respect to the fixed support unit 21. According to the edge detection device 20, the position of the edge of the substrate can be accurately detected more stably and in a shorter time as compared with the known edge detection method described above.

In the present embodiment, since the edge E3 of part of the active matrix substrate 2 is accurately detected using the alignment marks ALM1 and ALM2, and the conductive resins CR1 and CR2 are accurately applied to the predetermined positions of the edge E3, the function unit 22 of the edge detection device 20 includes a storage unit 23 for the conductive resins CR1 and CR2 as illustrated in FIG. 6. The nozzle 23N for discharging the conductive resins CR1 and CR2 toward the mounting stand 28 side is provided on a surface of the storage unit 23 facing the mounting stand 28. The control unit moves one of the mounting stand 28 and the function unit 22 with respect to the other of the mounting stand 28 and the function unit 22 based on the detected position of part of the edge of the active matrix substrate 2. That is, the edge detection device 20 illustrated in FIG. 6 further detects the application positions of the conductive resins CR1 and CR2 based on the detected position of the part of the edge E3 of the active matrix substrate 2 by using the alignment marks ALM1 and ALM2, and moves the nozzle 23N for discharging the conductive resins CR1 and CR2 to the application positions of the conductive resins CR1 and CR2. Thereafter, the control unit discharges the conductive resins CR1 and CR2 at the predetermined positions through the nozzle 23N, and the conductive resins CR1 and CR2 can be formed in a shape illustrated in FIG. 5. As illustrated in FIG. 6, the function unit 22 of the edge detection device 20 preferably includes a distance meter 25 that measures the distance between the active matrix substrate 2 provided in the display device 1 and the nozzle 23N in the Z direction. For example, a laser distance meter can be used as the distance meter 25. When the distance meter 25 is included, the nozzle 23N can be brought close to the display device 1 while measuring the distance between the active matrix substrate 2 and the nozzle 23N in the Z direction. When the distance meter 25 is not included, the control unit may lower the function unit 22 only by a certain distance in the Z direction.

In the present embodiment, as illustrated in FIG. 7, an example will be described in which in the edge detection device 20, a step of detecting and imaging the alignment mark ALM1 (S1), a step of detecting and imaging the alignment mark ALM2 (S2), a detection step of the application position of the conductive resin CR1 (S3), a detection step of the application position of the conductive resin CR2 (S4), an application step of the conductive resin CR1 (S5), and an application step of the conductive resin CR2 (S6) are performed in this order. However, the disclosure is not limited thereto. For example, one of the step (S1) and the step (S2) may be performed first, then the other of the step (S1) and the step (S2) may be performed, then one of the step (S3) and the step (S4) may be performed, then the other of the step (S3) and the step (S4) may be performed, then one of the step (S5) and the step (S6) may be performed, and then the other of the step (S5) and the step (S6) may be performed. Furthermore, after the step (S1), the step (S3), and the step (S5) are performed in this order, the step (S2), the step (S4), and the step (S6) may be performed in this order, or after the step (S2), the step (S4), and the step (S6) are performed in this order, the step (S1), the step (S3), and the step (S5) may be performed in this order.

In the step (S1) of detecting and imaging the alignment mark ALM1 illustrated in FIG. 7, as illustrated in FIG. 8, first, the control unit 29 provided in the edge detection device 20 reads out the data of the first image GZ1 in a plan view of the alignment mark ALM1 including the edge of the alignment mark ALM1 at which the cutting line SDL2 of the alignment mark ALM1 is located, the data being obtained beforehand by the image taking portion 24 and stored in the memory unit provided in the edge detection device 20, and compares the data with the data of the captured image obtained from the image taking portion 24. In order to stably detect the alignment mark ALM1 in a short time, this step performs teaching the alignment mark ALM1 to the edge detection device 20 in advance and performs pattern matching between the data of the captured image obtained from the image taking portion 24 and the data of the first image GZ1 that is a teaching image, so that the alignment mark ALM1 is detected in the captured image obtained from the image taking portion 24. In the detection step of the alignment mark ALM1 using such pattern matching, a portion having the same shape as that of the first image GZ1 that is the teaching image is searched from the captured image obtained from the image taking portion 24, and when the portion has a matching rate equal to or higher than a certain value, the portion is recognized as the alignment mark ALM1 and the position thereof is detected. In the present embodiment, as illustrated in FIG. 8, the data of the captured image obtained from the image taking portion 24 is the data of the second image GZ2 in a plan view of the alignment mark ALM1 including the edge of the alignment mark ALM1 at which the cutting line SDL2 of the alignment mark ALM1 is located. The control unit 29 can detect a position of part of the edge E3 of the active matrix substrate 2, for example, an intermediate position (a position in which dotted lines are orthogonal to each other in FIG. 8) which is part of the edge E3 of the active matrix substrate 2 and is a region in which the alignment mark ALM1 is provided as the detection position EP of the alignment mark ALM1. Also in the step (S2) of detecting and imaging the alignment mark ALM2 illustrated in FIG. 7, similarly to the step (S1) of detecting and imaging the alignment mark ALM1 illustrated in FIG. 7, the control unit 29 can detect a position of part of the edge E3 of the active matrix substrate 2, for example, an intermediate position which is part of the edge E3 of the active matrix substrate 2 and is a region in which the alignment mark ALM2 is provided as the detection position EP of the alignment mark ALM2.

In the detection step (S3) of the application position of the conductive resin CR1 illustrated in FIG. 7, the control unit 29 provided in the edge detection device 20 can detect a position moved by a predetermined distance from the detection position EP of the alignment mark ALM1 to the inner side of the active matrix substrate 2 along the edge E3 of the active matrix substrate 2 as the application position of the conductive resin CR1. As illustrated in FIG. 1, the position where the conductive resin CR1 is formed is predetermined distance away from the position where the alignment mark ALM1 is provided to the inside of the active matrix substrate 2 along the edge E3 of the active matrix substrate 2. Also in the detection step (S4) of the application position of the conductive resin CR2 illustrated in FIG. 7, similarly to the detection step (S3) of the application position of the conductive resin CR1 illustrated in FIG. 7, the control unit 29 can detect a position moved by a predetermined distance from the detection position EP of the alignment mark ALM2 to the inner side of the active matrix substrate 2 along the edge E3 of the active matrix substrate 2 as the application position of the conductive resin CR2.

According to the alignment marks ALM1 and ALM2 provided on the active matrix substrate 2, an alignment following a partition tolerance which may occur in the step of singulation by partitioning the mother display device including the plurality of display devices into the plurality of display devices can be performed, and the position of the edge of the active matrix substrate 2 can be accurately detected. Thus, the conductive resins CR1 and CR2 can be accurately and stably applied without being affected by the partition tolerance. The control unit 29 detects the position moved by the predetermined distance from the detection position EP of the alignment mark ALM1 to the inner side of the active matrix substrate 2 along the edge E3 of the active matrix substrate 2 as the application position of the conductive resin CR1, and moves the nozzle 23N for discharging the conductive resin CR1 to the detected application position of the conductive resin CR1. However, as illustrated in FIG. 9, when the display device 1 is ideally partitioned from the mother display device including the plurality of display devices without the partition tolerance, the nozzle 23N is accurately located on part of the edge E3 of the active matrix substrate 2. Further, as illustrated in FIG. 10, even when the display device 1 is partitioned from the mother display device including the plurality of display devices with the positive partition tolerance (for example, partition tolerance=+4.0 mm), the nozzle 23N is accurately located on part of the edge E3 of the active matrix substrate 2. Further, as illustrated in FIG. 11, even when the display device 1 is partitioned from the mother display device including the plurality of display devices with the negative partition tolerance (for example, partition tolerance=−4.0 mm), the nozzle 23N is accurately located on part of the edge E3 of the active matrix substrate 2.

In the step of detecting and imaging the known alignment mark ALM101, as illustrated in FIG. 12, first, the control unit 29 provided in the edge detection device 20 reads out the data of the first image GZ1 in a plan view of the known alignment mark ALM101, the data being obtained beforehand by the image taking portion 24 and stored in the memory unit provided in the edge detection device 20, and compares the data with the data of the captured image obtained from the image taking portion 24. As illustrated in FIG. 12, the data of the captured image obtained from the image taking portion 24 is the data of the second image GZ2 in a plan view of the known alignment mark ALM101. The control unit 29 can detect the center of the known alignment mark ALM101 as the detection position EP of the known alignment mark ALM101. In order to detect the application position of the conductive resin CR1 from the detection position EP of the known alignment mark ALM101, the control unit 29 first horizontally moves the detection position EP of the known alignment mark ALM101 toward the edge E3 side of the active matrix substrate 102 by the shortest distance DIS between the detection position EP of the known alignment mark ALM101 and the edge E3 of the active matrix substrate 102, and then a position moved by a predetermined distance to the inner side of the active matrix substrate 102 along the edge E3 of the active matrix substrate 102 can be detected as the application position of the conductive resin CR1. A illustrated in FIG. 13, when the known display device is ideally partitioned from the mother display device including the plurality of display devices without the partition tolerance, the nozzle 23N is accurately located on part of the edge E3 of the active matrix substrate 102. However, as illustrated in FIG. 14, when the known display device is partitioned from the mother display device including the plurality of display devices with the positive partition tolerance (for example, partition tolerance=+4.0 mm), the application position of the conductive resin CR1 detected by the control unit 29 is not on part of the edge E3 of the active matrix substrate 102 but on the inner side of the active matrix substrate 102 with respect to the edge E3 of the active matrix substrate 102, and the nozzle 23N is also not on part of the edge E3 of the active matrix substrate 102 but on the inner side of the active matrix substrate 102 with respect to the edge E3 of the active matrix substrate 102. As illustrated in FIG. 15, when the known display device is partitioned from the mother display device including the plurality of display devices with the negative partition tolerance (for example, partition tolerance=−4.0 mm), the application position of the conductive resin CR1 detected by the control unit 29 is not on part of the edge E3 of the active matrix substrate 102 but on the outer side of the edge E3 of the active matrix substrate 102, and the nozzle 23N is also not on part of the edge E3 of the active matrix substrate 102 but on the outer side with respect to the edge E3 of the active matrix substrate 102. As described above, in the case of the known alignment mark ALM101 provided on the active matrix substrate 102, alignment following the partition tolerance that may occur in the step of singulation by partitioning the mother display device including the plurality of display devices into the plurality of display devices is impossible, so the position of the edge of the active matrix substrate 102 cannot be accurately detected, and thus the conductive resin can be applied only with low accuracy due to a large influence of the partition tolerance.

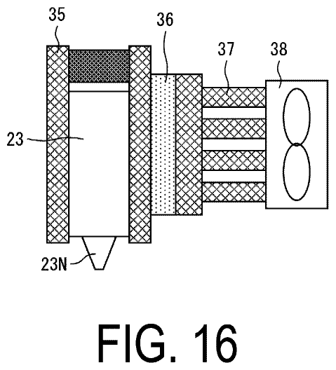

As illustrated in FIG. 16, the function unit 22 of the edge detection device 20 illustrated in FIG. 6 may further include a temperature adjustment portion 36 that adjusts a temperature of the storage unit 23 of the conductive resin. The temperature adjustment portion 36 may be, for example, a Peltier element, a heat sink portion 37 may be provided so as to be in contact with the temperature adjustment portion 36, and a fan 38 may be provided near the heat sink portion 37. In addition, a holder 35 that surrounds part of the storage unit 23 of the conductive resin may be provided. As illustrated in FIG. 16, by providing a temperature control mechanism that controls the temperature of the storage unit 23 of the conductive resin, the viscosity of the conductive resin can be kept constant, and a coating amount of the conductive resin can be further stabilized.

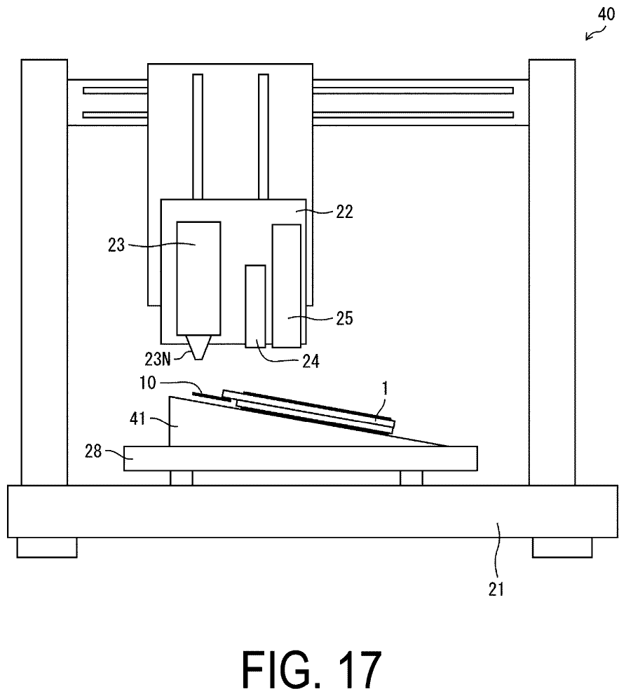

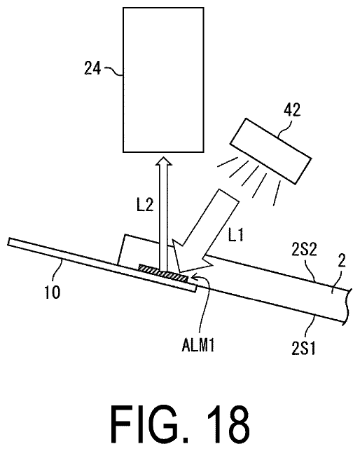

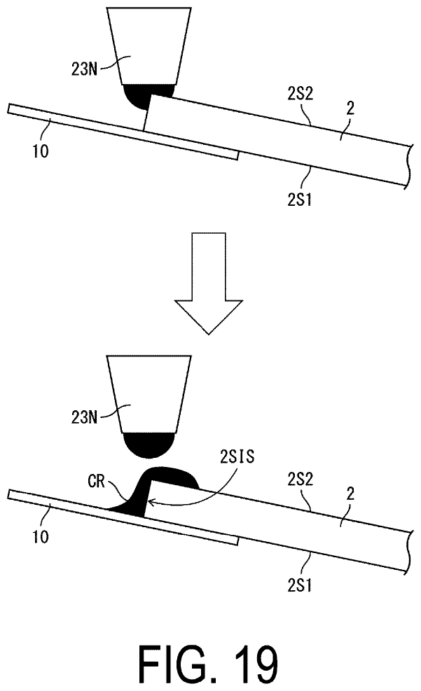

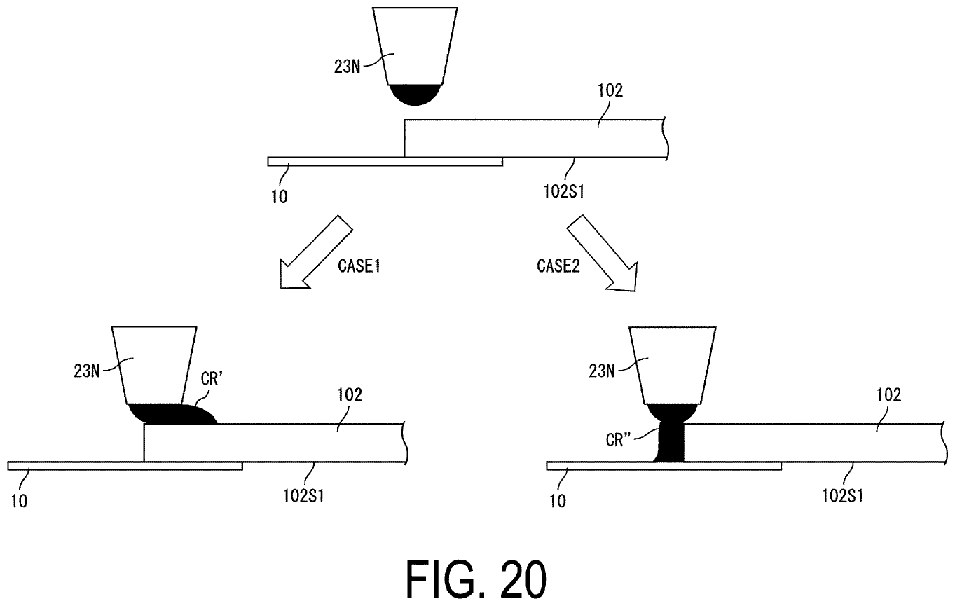

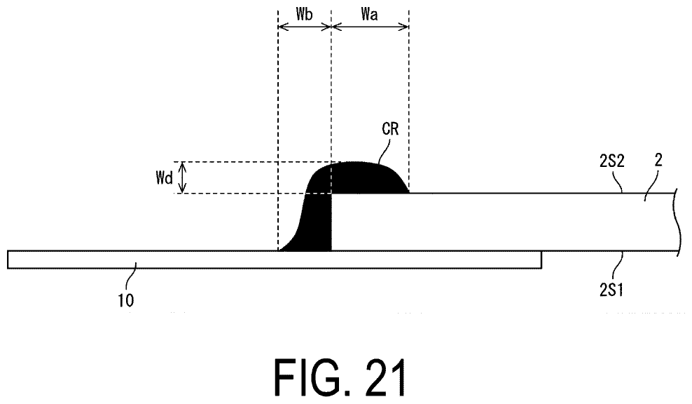

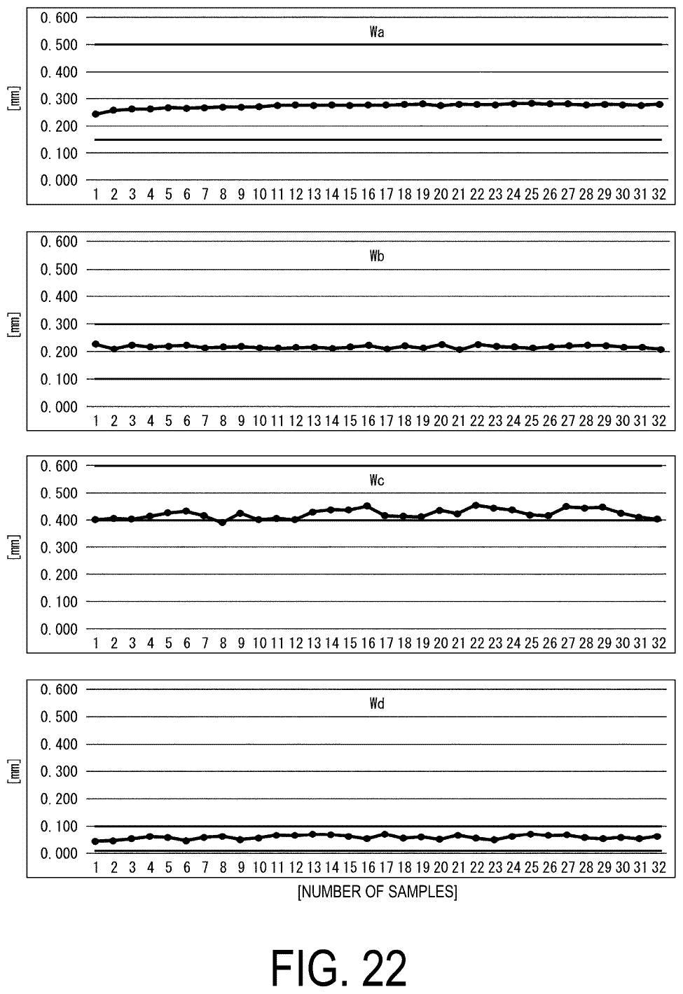

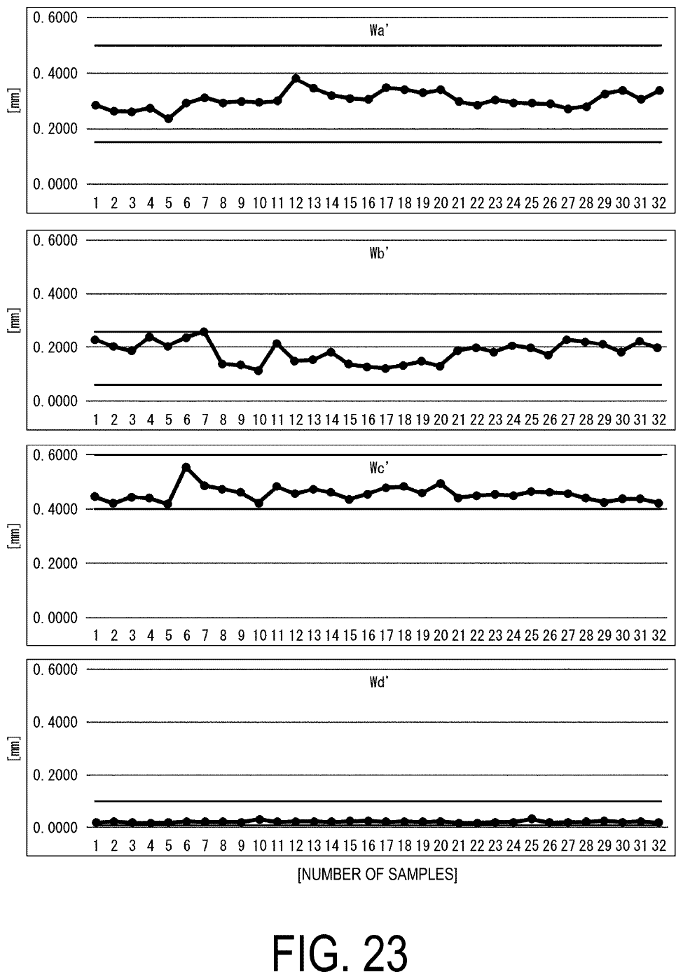

FIG. 17 is a view illustrating a schematic configuration of an edge detection device 40 including a tilt mechanism 41 that tilts the display device 1 according to the first embodiment including the active matrix substrate 2 including the alignment marks ALM1 and ALM2 at 45 degrees or less with respect to a plane. FIG. 18 is a view illustrating a case where the function unit 22 of the edge detection device 40 including the tilt mechanism 41 illustrated in FIG. 17 further includes a light radiation unit 42. FIG. 19 is views for describing a step of moving the nozzle 23N for discharging the conductive resin CR to the application position of the conductive resin CR detected by the edge detection device 40 illustrated in FIG. 17 and the application step of the conductive resin CR. FIG. 20 is a view for describing a problem in a step of applying conductive resins CR′ and CR″ to part of the edge of the active matrix substrate 102 including the known alignment mark ALM101. FIG. 21 is a view for describing finished dimensions of the conductive resin CR applied to the display device 1 according to the first embodiment. FIG. 22 is diagrams for describing the degrees of variations in the finished dimensions of the conductive resin CR applied to the display device 1 according to the first embodiment. FIG. 23 is diagrams for describing the degrees of variations in finished dimensions of the conductive resins CR′ and CR″ applied to the known display device including the active matrix substrate 102 including the known alignment mark ALM101.

As illustrated in FIG. 17, the mounting stand 28 included in the edge detection device 40 includes the tilt mechanism 41 that tilts the active matrix substrate 2 including the alignment marks ALM1 and ALM2 provided in the display device 1 at 45 degrees or less with respect to the plane so that part of the edge E3 of the active matrix substrate 2 approaches the nozzle 23N. In this case, data of the first image GZ1 and the second image GZ2, which are captured images obtained from the image taking portion 24 included in the edge detection device 40, are data obtained in a state where the active matrix substrate 2 is tilted. That is, the data of the first image GZ1 and the data of the second image GZ2 are data of captured images obtained by capturing, in a plan view, the plane, for example, the mounting stand 28, serving as a reference for the image taking portion 24 to tilt the active matrix substrate 2 in a state where the active matrix substrate 2 is tilted.

As illustrated in FIG. 18, the function unit 22 included in the edge detection device 40 preferably includes the light radiation unit 42. The light radiation unit 42 is provided at a position where at least part of light L1 emitted from the light radiation unit 42 is regularly reflected by the alignment marks ALM1 and ALM2 and is incident on the image taking portion 24 as light L2. Here, an example will be described in which one light radiation unit 42 is added. However, the disclosure is not limited thereto, and a plurality of the light radiation units 42 may be added. When the display device 1 is tilted on the mounting stand 28 of the edge detection device 40, a contrast difference between the alignment marks ALM1 and ALM2 and the surroundings thereof cannot be sufficiently obtained only by vertical illumination provided in the image taking portion 24. Thus, by additionally providing the light radiation unit 42, the recognition rate of the alignment marks ALM1 and ALM2 can be maintained high even when the display device 1 is tilted on the mounting stand 28 of the edge detection device 40.

As illustrated in FIG. 19, each of the step of moving the nozzle 23N for discharging the conductive resin CR to the application position of the conductive resin CR detected by the edge detection device 40 and the application step of the conductive resin CR are performed in a state where the active matrix substrate 2 is tilted at 45 degrees or less with respect to the plane so that part of the edge E3 of the active matrix substrate 2 approaches the nozzle 23N. As illustrated in FIG. 19, the conductive resin CR adheres to a tip of the nozzle 23N in a hemispherical shape. When the nozzle 23N is brought close to part of the edge E3 of the active matrix substrate 2, since the active matrix substrate 2 is tilted, the conductive resin CR adhering to the tip of the nozzle 23N is forcibly brought into contact with both the side surface 2SIS that is a cut surface of the active matrix substrate 2 and the second surface 252 of the active matrix substrate 2, so that both the side surface 2SIS and the second surface 2S2 of the active matrix substrate 2 can be wetted. As described above, ensuring of the wettability by the forcible contact of the conductive resin CR with both the side surface 2SIS and the second surface 2S2 of the active matrix substrate 2 triggers the conductive resin CR to stably flow to both the side surface 2SIS side of the active matrix substrate 2, that is, the flexible printed circuit board 10 side and the second surface 2S2 side of the active matrix substrate 2 in a balanced manner. The active matrix substrate 2 is preferably tilted at 45 degrees or less with respect to the plane, more preferably tilted at 5 degrees or more and 15 degrees or less with respect to the plane, and most preferably tilted at 10 degrees with respect to the plane so that part of the edge E3 of the active matrix substrate 2 approaches the nozzle 23N.

As illustrated in FIG. 20, the following problem arises in the step of applying the conductive resins CR′ and CR″ to part of the edge of the active matrix substrate 102 including the known alignment mark ALM101. When the known display device including the active matrix substrate 102 is partitioned so as to have the partition tolerance, as described above, the nozzle 23N is located not on part of the edge E3 of the active matrix substrate 102 but on the inner side of the active matrix substrate 102 or on the outer side with respect to the edge E3 of the active matrix substrate 102. When the nozzle 23N is located on the inner side of the active matrix substrate 102 and the active matrix substrate 102 is not tilted with respect to the plane (CASE1 illustrated in FIG. 20), due to the capillary phenomenon caused by a clearance between an upper face of the active matrix substrate 102 and the nozzle 23N, a phenomenon occurs in which the conductive resin CR′ flows only to the upper face side of the active matrix substrate 102 and does not flow down to the side surface side that is the cut surface of the active matrix substrate 102, that is, the flexible printed circuit board 10 side. Further, when the nozzle 23N is located on the outer side with respect to the edge E3 of the active matrix substrate 102 and the active matrix substrate 102 is not tilted with respect to the plane (CASE2 illustrated in FIG. 20), a phenomenon occurs in which the conductive resin CR″ does not flow to the upper face side of the active matrix substrate 102.

The shape of the conductive resin CR applied to the display device 1 in the state where the active matrix substrate 2 is tilted at 10 degrees with respect to the plane by the edge detection device 40 so that part of the edge E3 of the active matrix substrate 2 approaches the nozzle 23N as illustrated in FIG. 17 can be defined, as illustrated in FIG. 21, by a width Wa of the conductive resin CR formed on the second surface 2S2 of the active matrix substrate 2 in the first direction D1 (see FIG. 2), a width Wb of the conductive resin CR formed on the flexible printed circuit board 10 in the first direction D1 (see FIG. 2), a thickness Wd of the conductive resin CR formed on the second surface 22 of the active matrix substrate 2, and a width Wc (not illustrated) of the conductive resin CR in the second direction D2 (see FIG. 2) that is the depth direction of FIG. 21. It is important that each of the width Wa, the width Wb, the width Wc, and the thickness Wd is within a respective one of reference dimensions, and it is preferable that the a variation thereof is small. When each of the width Wa, the width Wb, the width Wc, and the thickness Wd deviates from the respective one of the reference dimensions, this leads to serious defects such as a decrease in a cross-sectional area of the conductive resin CR required for electrical connection, an increase in connection resistance due to a decrease in the cross-sectional area of the conductive resin CR on the first connection pads CP1 and CP1′ and the second connection pads CP2 and CP2′, interference with a backlight unit, and a decrease in the degree of bending of the flexible printed circuit board 10.

As illustrated in FIG. 22, in the state of being tilted at 10 degrees with respect to the plane, the degrees of variations in the finished dimensions of the conductive resin CR applied to the display device 1 including the active matrix substrate 2 including the alignment marks ALM1 and ALM2, that is, the degree of variation in each of the width Wa, the width Wb, the width Wc, and the thickness Wd, is small, and the conductive resin CR being stable can be obtained. On the other hand, as illustrated in FIG. 23, in the state where the active matrix substrate 102 is not tilted with respect to the plane, the degrees of variations in the finished dimensions of the conductive resins CR′ and CR″ applied to the known display device including the active matrix substrate 102 including the known alignment mark ALM101, that is, the degrees of variations in widths Wa′, Wb′, Wc′ and Wd′ corresponding to the widths Wa, Wb, Wc, and Wd, respectively, described above are relatively large, and only unstable conductive resins CR′ and CR″ are obtained.

### INDUSTRIAL APPLICABILITY

The disclosure can be used for a substrate including an alignment mark and an edge detection device for a substrate including an alignment mark.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A substrate including an alignment mark comprising:
a substrate; and
an alignment mark provided on part of a first surface that is a surface on one side of the substrate,
wherein each of the substrate and the alignment mark has a cutting line, and
the cutting line of the alignment mark coincides with the cutting line of the substrate in a plan view.

2. The substrate including an alignment mark according to claim 1,
wherein the substrate includes a first region, and a second region surrounding the first region and including all edges of the substrate, and
the alignment mark is provided in the second region and is a continuous film formed from an edge of part of the substrate in a first direction that is a direction orthogonal to the edge of the part of the substrate.

3. The substrate including an alignment mark according to claim 2,
wherein the alignment mark is composed of a plurality of the continuous films.

4. The substrate including an alignment mark according to claim 3,
wherein the first region is a display region,
the second region is a non-display region, and
the substrate is an active matrix substrate including a plurality of pixel electrodes on the first surface in the display region, and
the alignment mark on the first surface in the non-display region.

5. The substrate including an alignment mark according to claim 4,
wherein the active matrix substrate is a glass substrate or an optical transparent resin substrate that is provided with the pixel electrode and the alignment mark,
the active matrix substrate includes a flexible printed circuit board including a first connection pad,
a wiring line pattern including a second connection pad is provided on a second surface facing the first surface in the non-display region of the active matrix substrate, and
the flexible printed circuit board is provided on part of the first surface in the non-display region of the active matrix substrate and the first connection pad is located near the second connection pad.

6. The substrate including an alignment mark according to claim 5,
wherein a counter substrate facing the pixel electrode of the active matrix substrate is provided on a first surface side of the active matrix substrate, and
a liquid crystal layer is further provided between the pixel electrode of the active matrix substrate and the counter substrate.

7. The substrate including an alignment mark according to claim 6,
wherein a conductive resin is provided as a continuous film on at least part of the first connection pad, at least part of the second connection pad, and a side surface of an edge of part of the active matrix substrate between the first connection pad and the second connection pad.

8. An edge detection device for a substrate including an alignment mark comprising:
a mounting stand on which the substrate including an alignment mark according to claim 1 is mounted;
a function unit including an image taking portion configured to image the alignment mark;
a memory unit in which data of a first image in a plan view of the alignment mark including an edge of the alignment mark at which a cutting line of the alignment mark is located, obtained from the image taking portion, is stored; and
a control unit configured to detect a position of part of the edge of the substrate by comparing data of a second image in a plan view of the alignment mark including the edge of the alignment mark at which the cutting line of the alignment mark is located, obtained from the image taking portion, with the data of the first image in the memory unit,
wherein one of the mounting stand and the function unit is movable with respect to the other of the mounting stand and the function unit in each of an X direction, a Y direction, and a Z direction.

9. The edge detection device for a substrate including an alignment mark according to claim 8,
wherein the function unit includes a storage unit of a conductive resin,
a nozzle configured to discharge the conductive resin toward a mounting stand side is included on a surface of the storage unit facing the mounting stand, and
the control unit moves one of the mounting stand and the function unit with respect to the other of the mounting stand and the function unit based on the detected position of part of the edge of the substrate.

10. The edge detection device for a substrate including an alignment mark according to claim 9,
wherein the function unit includes a temperature adjustment portion configured to adjust a temperature of the storage unit of the conductive resin.

11. The edge detection device for a substrate including an alignment mark according to claim 9,
wherein the mounting stand includes a tilt mechanism configured to tilt the substrate including an alignment mark at 45 degrees or less with respect to a plane so that part of the edge of the substrate approaches the nozzle, and
data of the first image and data of the second image are data obtained in a state where the substrate including an alignment mark is tilted.

12. The edge detection device for a substrate including an alignment mark according to claim 11,
wherein the function unit includes a light radiation unit, and
the light radiation unit is provided at a position where at least part of light emitted from the light radiation unit is regularly reflected by the alignment mark and is incident on the image taking portion.
